(19) United States
(12) Patent Application Publication
(10) Pub. No.: US 2009/0066353 A1
(43) Pub. Date: Mar. 12, 2009

(54) PROBE ASSEMBLIES AND METHODS FOR HOUSING AND PROVIDING ELECTRICAL CONTACT TO PLANAR OR CHIP-TYPE SENSORS AND HEATERS

(75) Inventors: Andrew D. Devey, Reno, NV (US); James Delbert Parsons, Reno, NV (US)

Correspondence Address: KOPPEL, PATRICK & HEYBL, 555 ST. CHARLES DRIVE, SUITE 107, THOUSAND OAKS, CA, 91360, US

(73) Assignee: HEETRONIX

(21) Appl. No.: 12/200,626

(22) Filed: Aug. 28, 2008

Related U.S. Application Data
(60) Provisional application No. 60/966,814, filed on Aug. 29, 2007.

(51) Int. Cl. G01R 1/067; G01R 31/02

(52) U.S. Cl. 324/757

(57) ABSTRACT

A probe assembly for planar or chip-type sensors and heaters, which includes a probe housing having a tip end and a feed-through end, and a sensor or heater element within the housing which includes electrode pads and has a bottom surface that is in thermal contact with the probe tip. The assembly includes a means of applying a first compressive force to the element such that thermal contact between its bottom surface and the probe tip is maintained. Electrical lead wires (ELWs) within the housing provide respective conductive paths between the electrode pads and the feed-through end, each ELW including at least one spring portion which provides a second compressive force that acts to maintain physical and electrical contact between the ELW and its respective electrode pad. The assembly is arranged such that the first compressive force is independent of the second compressive force.

### RELATED APPLICATIONS

This application claims the benefit of provisional patent application No. 60/966,814 to Andrew D. Devey and James D. Parsons, filed Aug. 29, 2007.

### BACKGROUND OF THE INVENTION

1. Field of the Invention

This invention relates generally to methods and structures for housing and providing electrical contact to planar or chip type sensors and heaters.

2. Description of the Related Art

A sensor or heater element which needs to be deployed in a particular environment often requires a means of conveniently introducing the element into the environment, while at the same time protecting the element from the environment. One way of accomplishing this is by incorporating the element into a ‘probe’—i.e., a hollow, tubular, metallic or ceramic housing which contains a sensor and/or heater element located at one end of the housing (called the probe ‘tip’). The element can be, for example, a thermocouple, thermistor, resistance temperature detector (RTD) or a heater. Electrical lead wires extend from the element at the tip end of the housing, to a terminal or feed-through at the opposite end of the housing.

Probes of this sort have many applications. For example, a probe of this sort can be designed to be deployed into enclosures in which the temperature is controlled independently of the outside environment, e.g., autoclaves and furnaces. They might also be designed for us in enclosures containing gases and liquids, e.g., pipelines and constant temperature baths, etc., or within air flows and variable pressure environments for anemometry, temperature and pressure measurements and heating purposes.

There are several problems that can afflict probes of this sort. For example, when a sensor element is completely enclosed within the probe housing, the probe's response time is affected by the contact interface between the housing wall and the sensor. Response time can be further compromised if the sensor is, for example, a platinum wire-wound RTD. This type of sensor must be embedded in alumina or some other compressed and sintered ceramic having poor thermal conductivity, in which case the sensor element itself does not make good thermal contact with the inside wall of the housing.

Heat or the sensed parameter (typically temperature, pressure and/or flow rate) is transmitted to or from the element to a surface or an environment, to measure and/or heat the surface or environment. Conventionally, electrical lead wires are welded, bonded, brazed or soldered to the element. This requires that planar or chip-type sensors to be oriented with their electrodes parallel to the probe axis, with their edges in contact with the probe tip. However, good thermal contact between planar or chip-type sensors and the probe tip is best achieved when the sensor is oriented so that the surface containing electrodes is perpendicular to the probe axis, with the electrode pads facing towards the terminal or feed-through end of the probe. Reliable bonding, welding or soldering of lead wires to sensor electrode pads is extremely difficult in this configuration, which serves to limit the applications in which planar and chip-type sensors are employed.

Additional problems can arise for probes which are subjected to a range of temperatures. Typically, the lead wires, element and probe housing would have different expansion coefficients. As such, with the lead wires bonded to the element and the element bonded to the housing, differences between the respective expansion coefficients can cause the probe to fail or become unreliable as its components expand and contract with varying temperature.

### SUMMARY OF THE INVENTION

Probe assemblies and methods for housing and providing electrical contact to planar or chip-type sensors and heaters are presented. The probe assemblies address several of the problems noted above. For example, they enable sensors or heating elements to be oriented with their electrode pads perpendicular to the probe axis while still providing good thermal contact between element and probe tip. In addition, the present probe assemblies are also arranged to reliably tolerate components having different expansion coefficients.

A probe assembly in accordance with the present invention is designed to house and provide electrical contact to planar or chip-type sensors and heaters. The assembly includes:

a probe housing having a tip end and a feed-through end and an associated longitudinal axis;

a sensor or heater element within the housing, the element having top and bottom surfaces, the top surface including electrode pads for the element, the assembly arranged such that the bottom surface is in thermal contact with the probe tip and the top and bottom surfaces are perpendicular to the longitudinal axis;

a means of applying a first compressive force to the sensor or heater element such that thermal contact between the bottom surface and probe tip is maintained; and

electrical lead wires (ELWs) within the housing which provide respective conductive paths between the electrode pads and the feed-through end, each ELW including at least one spring portion which provides a second compressive force that acts to maintain physical and electrical contact between the ELW and its respective electrode pad;

the assembly arranged such that the first compressive force is independent of the second compressive force.

A probe assembly arranged as described herein can increase the sensor's sensitivity and temperature range, and can reduce the sensor's response time. The assembly ensures that the sensor is held tightly against the probe tip under all thermal cycling conditions, over its entire temperature range, by a dynamic force applied parallel to the probe's longitudinal axis. Similarly, electrical contact between the electrode pads and the lead wires is maintained with an independent opposed force. This unique design provides for independent, dynamic, opposed forces, applied parallel to the longitudinal axis, maintaining contact of all relevant components at all probe temperatures and thermal cycling conditions. No welding, bonding, brazing or soldering is required inside the probe housing. Assemblies can also be provided in which the atmosphere within the probe housing can be controlled.

These and other features, aspects, and advantages of the present invention will become better understood with reference to the following drawings, description, and claims.

### BRIEF DESCRIPTION OF THE DRAWINGS

FIGS. 1a and 1b are a cutaway view and an elevation view with the probe sheath removed, respectively, of a probe assembly per the present invention.

FIG. 2 is an isometric cutaway view of a probe housing per the present invention.

FIGS. 3-6 are sectional views of various probe tips that might be used with a probe assembly per the present invention.

FIGS. 7-9 depicts various sensor or heater elements that might be deployed within a probe assembly per the present invention.

FIGS. 10-11 are sectional views of two possible electrical contact standoffs (ECS) that might be used with a probe assembly per the present invention.

FIGS. 12-13 depict two possible electrical lead-wire (ELW) embodiments per the present invention.

FIGS. 14-17 are sectional views of possible ELW embodiments that employ piston junctions.

FIGS. 18-20 are perspective views of three possible embodiments of a sensor/lead-wire alignment junction (SLWAJ) that might be used with a probe assembly per the present invention.

FIG. 21 is a sectional view of a SLWAJ with incoming ELWs as might be used with a probe assembly per the present invention.

FIGS. 22-25 are sectional views of possible lead-wire guide assemblies (LWGAS) that might be used with a probe assembly per the present invention.

FIG. 26 is a sectional view of a portion of a probe assembly illustrating the use of large and small conduit tubes.

FIG. 27 is a sectional view of a portion of a probe assembly illustrating an electrical feed-through (EFT) which employs a piston junction.

FIGS. 28 and 29 are sectional views of probe assemblies having an angled probe housing (APH).

FIG. 30 is a perspective view of an SLWAJ that includes diffusion paths.

FIG. 31 is a sectional view of a probe assembly having an APH and which includes features for providing atmosphere control.

### DETAILED DESCRIPTION OF THE INVENTION

The present probe assemblies provide for a means of housing and providing electrical contact to planar, thin-film and chip-type sensor and heater elements (“elements”), such that:

the element surface is oriented such that it is perpendicular to the probe housing's longitudinal axis;

the element surface containing the electrical contact pads (“electrode pads”) faces the terminal or feed-through end of the probe housing;

the element is held tightly against the probe housing tip under all thermal cycling conditions by dynamic, opposed forces, applied parallel to the longitudinal axis;

the electrical contact between the electrode pads and the lead wires (ELWs) is maintained by independent, dynamic, opposed forces, applied parallel to the longitudinal axis, at all probe temperatures and all thermal cycling conditions.

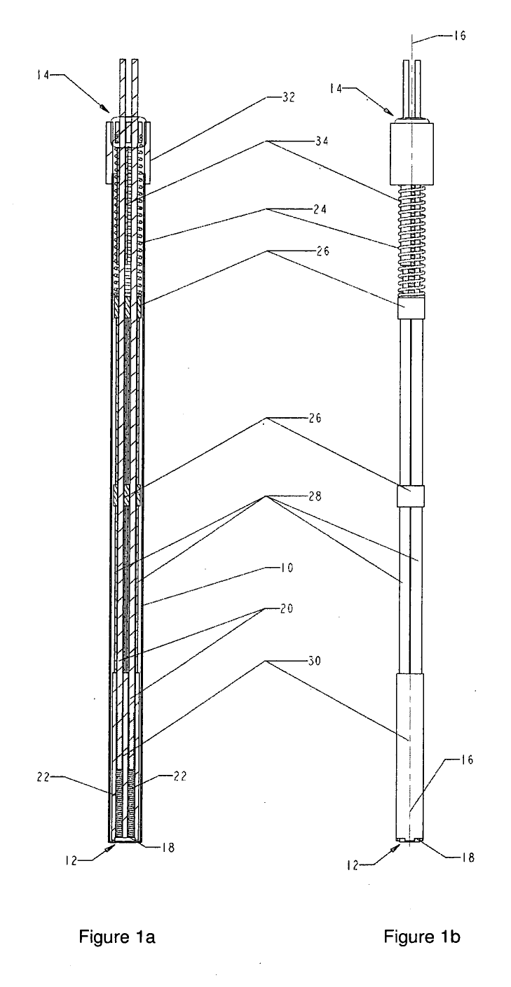

There are numerous ways in which a probe assembly in accordance with the present invention might be implemented. An embodiment illustrating the basic principles of the present probe assembly is shown in FIGS. 1a and 1b: FIG. 1a is a cutaway view of a probe assembly including a probe housing 10, and FIG. 1b is an elevation view of the assembly with housing 10 not shown. Note that, in practice, a probe assembly would typically be narrower than that shown in FIGS. 1a and 1b; these figures have been magnified laterally in order to more clearly show the assembly's features. Probe housing 10 has a tip end 12, a feed-through end 14 and an associated longitudinal axis 16.

A sensor or heater element 18 is within housing 10, with the top surface of the element including electrode pads by which connection is made to the element. The assembly is arranged such that the element's bottom surface is in thermal contact with the probe tip, and the element's top and bottom surfaces are perpendicular to longitudinal axis 16.

Signals are conveyed to element 18 via electrical lead wires (ELWs) within said housing which provide respective conductive paths between each of the electrode pads and feed-through end 14. Each ELW typically includes a wire portion 20 and a means of applying a first compressive force that acts to maintain physical and electrical contact between the ELW and its respective electrode pad; a preferred means for applying the first compressive force is a spring.

The assembly includes a means of applying a second compressive force to element 18 such that thermal contact between the element's bottom surface and the probe tip is maintained. In this exemplary embodiment, the second compressive force is applied via a preload spring 24. The assembly is arranged such that the first compressive force is independent of the second compressive force.

There are numerous ways in which thermal contact between element 18 and the probe tip can be maintained. Here, a lead wire guide assembly (LWGA) is provided between spring 24 and element 18, which consists of 2-hole insulating conduit tubes 26 and single insulating conduit tubes 28 through which ELWs 20 pass. These components are stacked between preload spring 24 and an alignment junction 30. Alignment junction 30 is arranged to fit over and press on the top of element 18, and to act as an alignment device for lead wires 20 and springs 22. The alignment junction includes guide holes, such that when in place over element 18, ELWs passing through the guide holes are aligned with and allowed to come into contact with the element's electrode pads. In this example, single insulating conduit tubes 28 press against the top surface of alignment junction 30, such that the force applied by preload spring 24 is conveyed to element 18 via conduit tubes 26 and 28, and alignment junction 30.

This exemplary embodiment also includes a feed-through 32 affixed to housing 10, and another insulating conduit tube 34 is affixed to feed-through 32 to provide isolation between the two ELWs. ELWs 20 pass through and are affixed to feed-through 32 (with one ELW passing through tube 34), and then are routed via conduit tubes 26 and 28 to element 18. When so arranged, ELW spring portions 22 are compressed by ELW wire portions 20, independently of the compressive force being applied by preload spring 24. Spring portions 22 may be separate from, or contiguous with, wires 20.

When so arranged, all internal components may expand and move independently. That is, element 18 and conduit tubes 26 and 28 move and/or expand with preload spring 24, while ELWs 20, 22 move and/or expand with feed-through 32, conduit tube 34 and probe housing 10. It is important that the assembly be constructed in such a way that each of the internal components move freely, with minimal frictional forces. The assembly ensures that sensor 18 is held tightly against the tip end 12 of probe housing 10 under all thermal cycling conditions by dynamic, opposed forces applied parallel to the probe's longitudinal axis, thereby ensuring good contact between the sensor and housing. Similarly, electrical contact between the electrode pads and ELWs 20, 22 is maintained by independent, dynamic, opposed forces, applied parallel to the longitudinal axis, at all probe temperatures and thermal cycling conditions. A probe assembly as described herein can function properly over a dynamic temperature range greater than that offered by previous designs; such probes have been demonstrated to successfully operate over a dynamic temperature range of −170° C. to 1500° C.

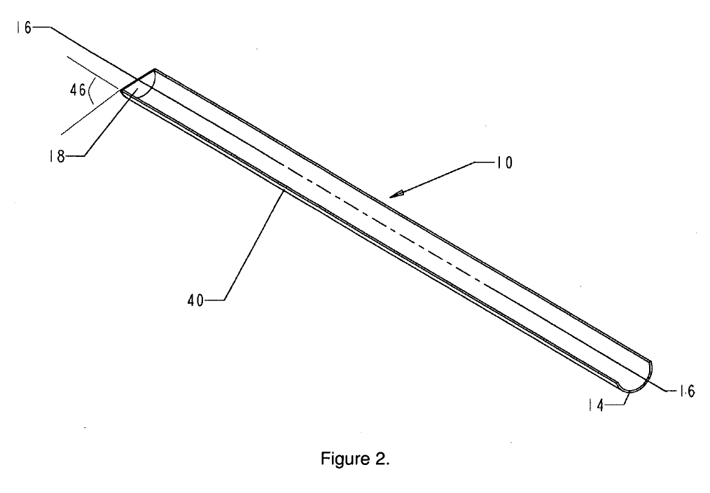

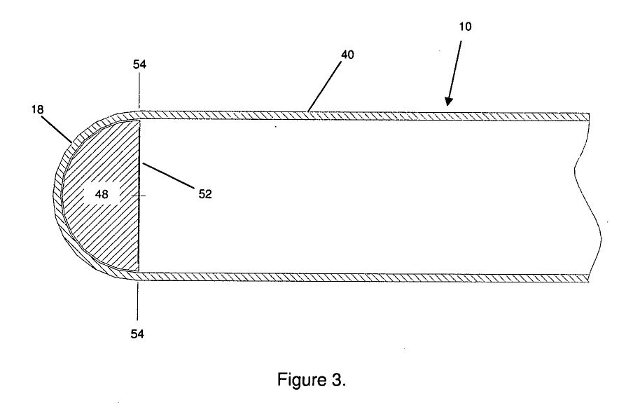

A cutaway view of a typical probe housing 10 is shown in FIG. 2. A probe housing is a hollow, tubular structure. The cross-section of the probe's walls perpendicular to the probe's longitudinal axis 16 may be circular, oval, rectangular or square. A probe housing may be comprised of multiple sections, each of different diameter or cross-section (e.g., increasing from tip end 18 to feed-through end 14), with the diameter or cross-section of each section being perpendicular to longitudinal axis 16. For purposes of illustration, a probe housing having a uniform circular cross-section is shown in FIG. 2; however, other cross-section shapes are suitable, as long as the shape of the outside surfaces of components that make contact with the probe walls are changed to conform to the different cross-section, and dimensional and thermal expansion matching constraints are retained.

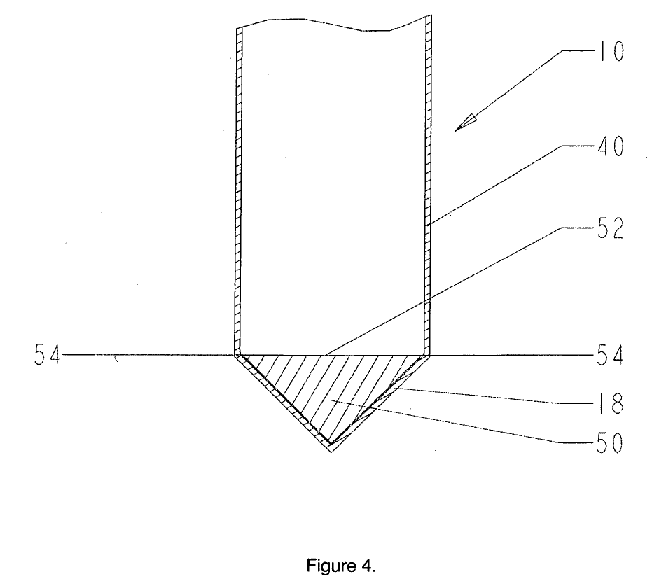

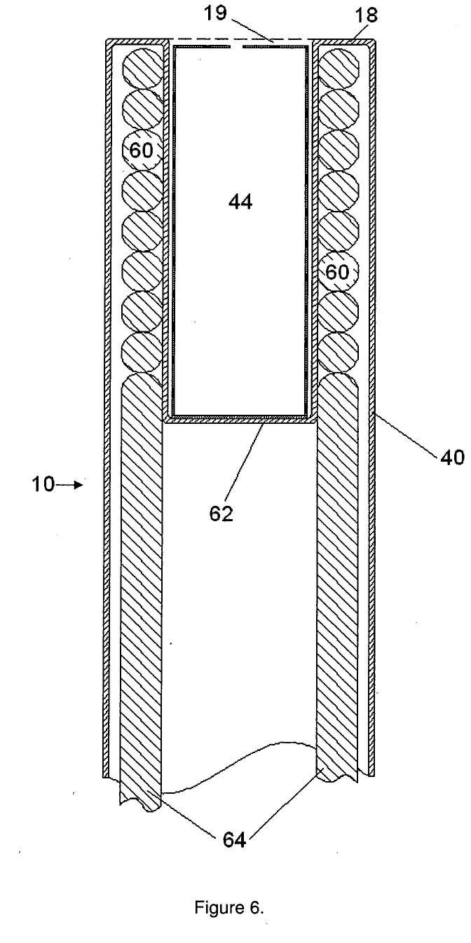

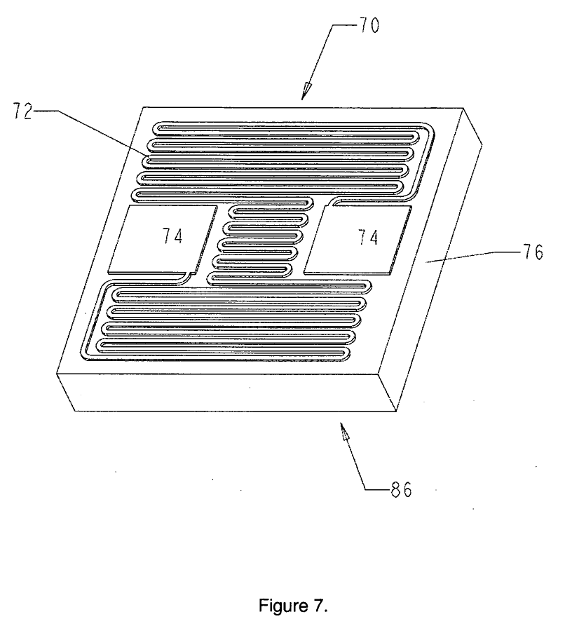

The probe housing 10 includes tip 18, terminal or feed-through end 14 and wall 40 (parallel to longitudinal axis 16). Probe tip 18 may have any one of a number of shapes. For example, tip 18 can be flat as shown in FIG. 2, rounded (FIG. 3); conical (FIG. 4), designed for an extension attachment to accommodate the attachment of special tips 42 (FIG. 4), or designed with a recessed tip for holding members 44 (FIG. 6).

Referring back to FIG. 2, the included angle 46 at the junction between probe wall 40 and a flat probe tip should be less than or equal to 90°. As used herein, a ‘flat’ tip include tips that are concave towards the sensor or heater element.

The shape of probe tip 18 must not prevent the sensor or heater element from making direct contact with the tip. If necessary, a thermal contact insert (TCI) should be included between probe tip 18 and the element. Appropriate TCIs 48, 50 for a rounded tip and a conical tip are illustrated in FIGS. 3 and 4, respectively.

Probe housing 10 can be metal, metal alloy or ceramic; considerations for the housing material include the temperature and environment in which the probe assembly is to be used, and its response time requirements. A metal probe housing with a flat tip 18 can be fabricated by machining or stamping, or a flat tip may be welded, brazed or soldered the to housing walls 40. A ceramic probe housing with a flat tip 18 can be fabricated by casting or grinding, or by adhesive bonding of a ceramic disk to housing walls 40. The expansion coefficient of probe tip 18 should be equal to or less than that of the probe housing walls 40.

Though the tip and feed-through ends of probe housing 10 are shown as aligned lying along longitudinal axis 16 in FIG. 2, housing 10 might alternatively be angled so that the feed-through end is offset from axis 16; this option is discussed in more detail below.

Thermal contact inserts, such as TCIs 48 and 50 shown in FIGS. 3 and 4, serve to stabilize the position of the sensor or heater element (not shown), align the element's electrode pads approximately perpendicular to longitudinal axis 16, and provide a thermal contact path between the element and probe tip 18. TCIs can be metals, metal alloys or ceramics, with probe response time decreasing with increasing TCI thermal conductivity. The top surface 52 of a TCI should be at or above the line 54 at which the outer diameter (OD) of probe tip 18 equals the maximum OD of the probe wall 40 under all conditions, so that the TCI's top surface 52 remains in contact with the bottom surface of the sensor or heater element at all times.

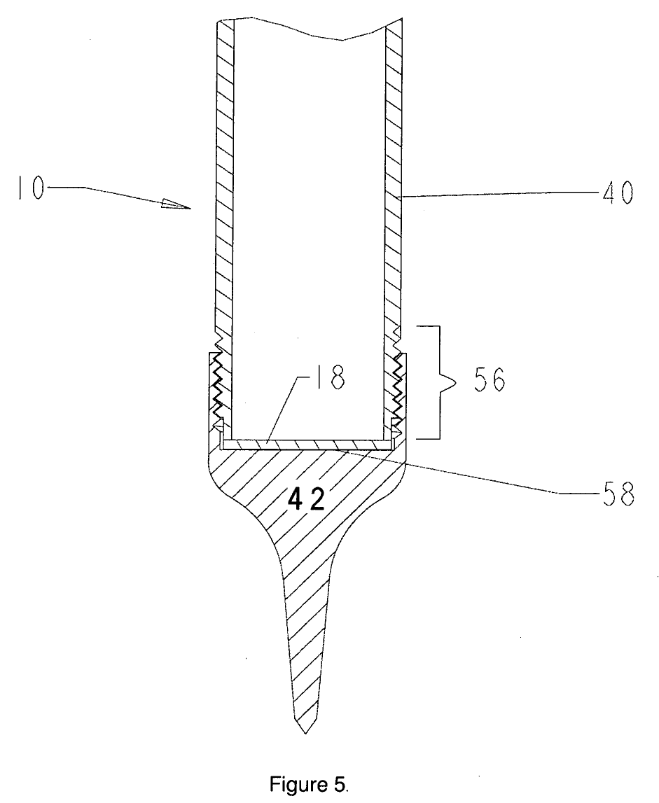

As noted above, FIG. 5 is an illustration of a probe tip 18 designed for an extension attachment, such as a solder tip 42 as shown here. In this exemplary embodiment, the housing wall 40 includes a threaded portion 56, on which an attachment 42 having corresponding threads can be screwed. Here, probe tip 18 is flat, and solder tip 42 is screwed onto threaded portion 56 such that the ‘bottom’ of the solder tip 58 is in contact with the flat tip 18. Many probe tip extension and connection designs, sizes, shapes and purposes are possible; the critical requirement is that there be good thermal contact between a sensor or heater element and the extension attachment. The probe housing, probe tip and extension attachment material should be selected such that the bottom 58 of the attachment remains in contact with the probe tip during heating and cooling.

FIG. 6 illustrates the use of a recessed tip 18 for holding members 44. The member being held may be, for example, a Knudsen cell. A resistively heated coil 60 may be used to heat the Knudsen cell, with the temperature of the Knudsen cell is monitored by a sensor (not shown) that would be pressed against the flat surface 62 of the recess. The heated coil would be powered via ELWs 64 routed through the probe assembly.

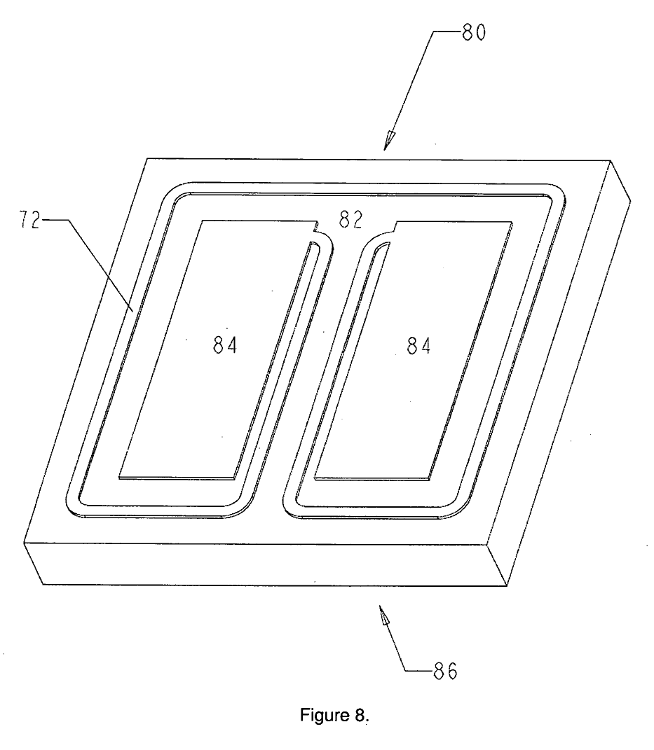

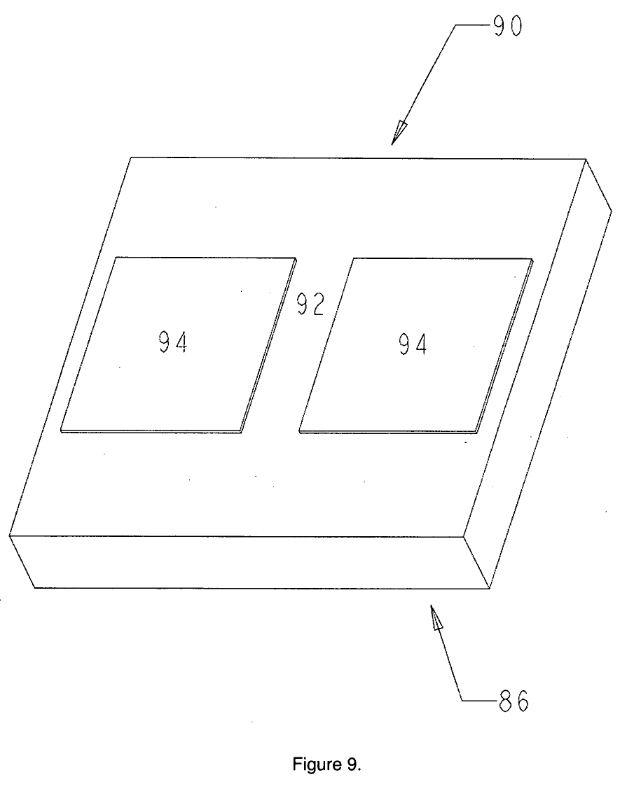

Several possible sensor or heater elements are illustrated in FIGS. 7-9. The surface cross-section of the elements can be rectangular, oval or round. A exemplary planar thin-film 2-wire sensor 70 is shown in FIG. 7, which comprises thin- or thick-film metallic strands 72 and electrode pads 74 on an electrically insulating ceramic base 76. Another example of a thin-film 2-wire sensor 80 with metallic strands 72 and electrode pads 84 is shown in FIG. 8.

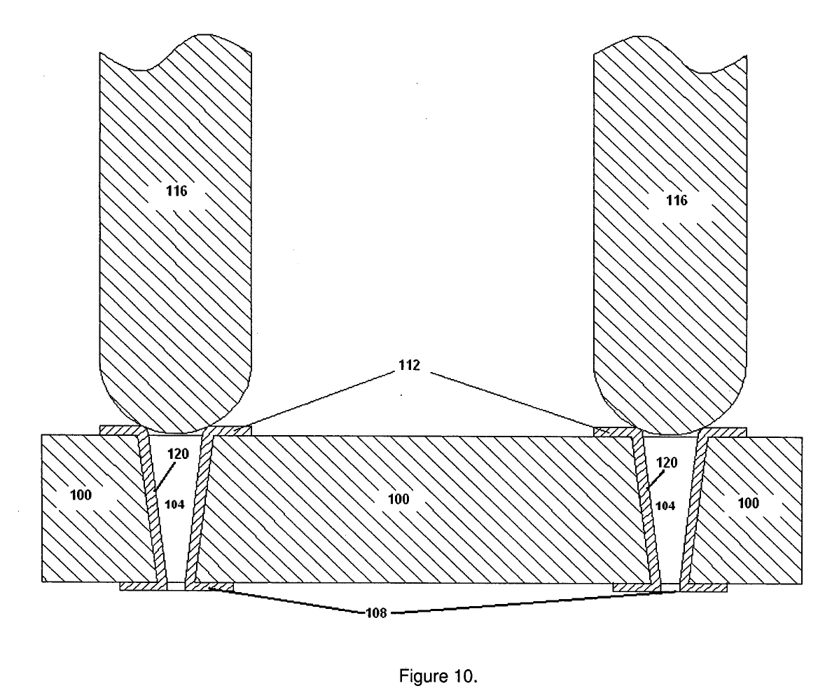

Thermistor and semiconductor sensors are typically square or rectangular chips; an example is shown in FIG. 9. Here, the sensor 90 is comprised of the chip 92 with metallic electrode pads 94 located on opposite ends of the chip surface. The electrical contacts formed by the electrode pads and the chip may be ohmic or rectifying.

The thickness of a sensor or heater element should be sufficient to ensure that it can be securely retained and kept in contact with the surface of the probe tip or TCI and the ELWs at all temperatures. In addition, the length and width dimensions of a sensor or heater element should be such that the longest edge to edge dimension of the element is 0.0005″ less than the inner diameter of the probe housing over the entire temperature range of the probe assembly.

The bottom surface 86 of a thin-film sensor as shown in FIGS. 7 and 8 may rest on an electrically conductive surface. The bottom surface 86 of thermistor or semiconductor chip as shown in FIG. 9 may rest on an electrically conductive surface, as long as an electrically insulating layer isolates the chip from the conductive surface. For example, an electrically insulating, ceramic chip having a thickness of at least 0.001″ could be placed between the back surface 86 of a bare thermistor or semiconductor chip 92 and an electrically conductive surface.

An electrical contact standoff (ECS) may be inserted between the tips of the ELWs and the sensor or heater element, to spread the force of the ELW tips over a larger area and thereby reduce the possibility of the ELW cracking the element or scratching its electrode pads.

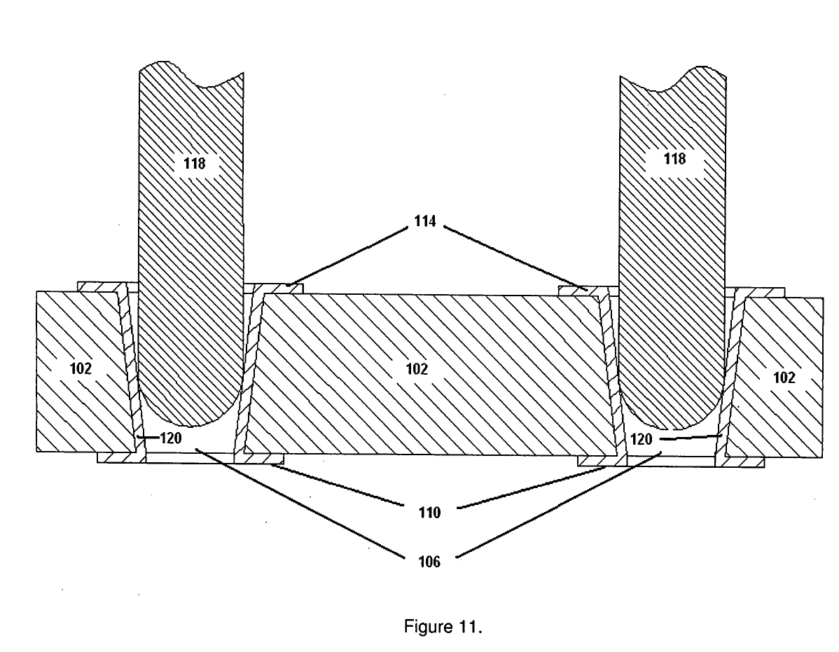

Exemplary ECS embodiments are shown in FIGS. 10-11. An ECS is preferably made from an electrically insulating ceramic sheet 100, 102 that is the same length and width as the element with which it is mated; the expansion coefficients of the element and ECS should match each other as closely as possible. Vias 104, 106 are formed through the sheet, the bottom sides of which form pads (108, 110) which are arranged to align with the electrode pads of a sensor or heater element an ECS and element are aligned with each other.

The top sides of vias 104, 106 also form pads 112, 114. If, as in FIG. 10, the tips 116 of the ELWs are to rest on top pads 112, then the diameter of the vias must be less than the diameter of the ELW tip with which it is in contact, and the thickness of ECS ceramic sheet 100 should be at least 0.01″. If, as in FIG. 11, the tips 118 of the ELWs are to rest inside vias 106, then the thickness of ECS ceramic sheet 102 should be at least four times the diameter of the vias.

The vias 104, 106 contain electrically conductive material 120 (metal or graphite) which provides electrical continuity between the vias' bottom pads 108, 110 and top pads 112, 114, or between the ELW tip 118 and bottom pads 110 (FIG. 11). A via can be filled with electrically conductive material 120, or the walls of a via can be coated with an electrically conductive material, as shown in FIGS. 10 and 11. Electrically conductive material 120 can be applied to the ECS vias and pad areas by screen printing or thin-film deposition processes such as sputtering, evaporation and chemical vapor deposition. Lithographic processes can be used to selectively remove the conductive material from areas where it is not wanted.

The length and width dimensions of each top pad 112, 114 should be greater than the diameter of the ELW tip 116, 118, and should not make contact with other top pads. The length and width dimensions of each bottom pad 108, 110 should be less than or equal to the length and width dimensions of the element electrode pads (not shown), so that when an ECS is aligned with an element, bottom pads 108, 110 are in contact only with the electrode pads. The thickness of the electrically conductive material 120 inside the vias and on the bottom pads 108, 110 should be at least 1,000 Å.

The exemplary electrical contact standoffs shown in FIGS. 10 and 11 each contain two vias, which align with corresponding electrode pads on a sensor or heater element when the element and ECS are aligned with each other. A 4-wire ECS, not shown, would contain four vias, which might be arranged such that two vias align with each electrode pad, or such that each of the four vias aligns with a respective electrode pad. When two ECS vias align with a single electrode pad, each of the two vias could extend between two separate bottom pads and two separate top pads, or the two vias could extend between a shared bottom pad and a shared top pad. An ECS having a number of vias other than two or four might also be used for some applications.

As noted above, each ELW typically includes a wire portion and at least one spring portion. An ELW should be constructed in such a way that its length and the length of the probe housing can change independently. An ELW should be compressively loaded at all times, and at the same time remain aligned with the probe's longitudinal axis 16 along the entire length of the housing. This is most effectively accomplished using coiled springs.

Therefore, each ELW preferably comprises a coiled spring along its entire length, or contains a coiled spring as a part of its length. The coiled spring provides the flexible opposed forces required for the ELW to exert a positive force, parallel to the longitudinal axis, on the electrode pads of a sensor or heater element, or on the top pads of an ECS, regardless of expansion coefficient differences between the probe housing and the ELW. The metal or metallic alloy used for the wire portion of an ELW and the metal or metallic alloy used for the spring portion of an ELW may be different.

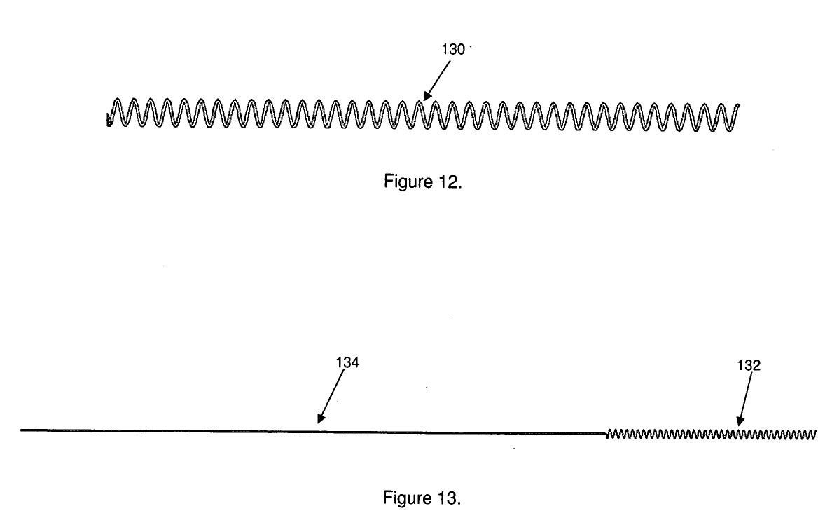

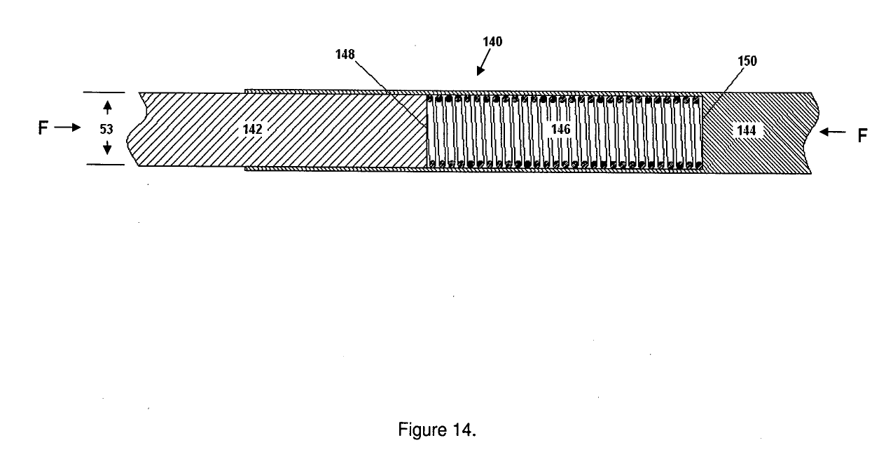

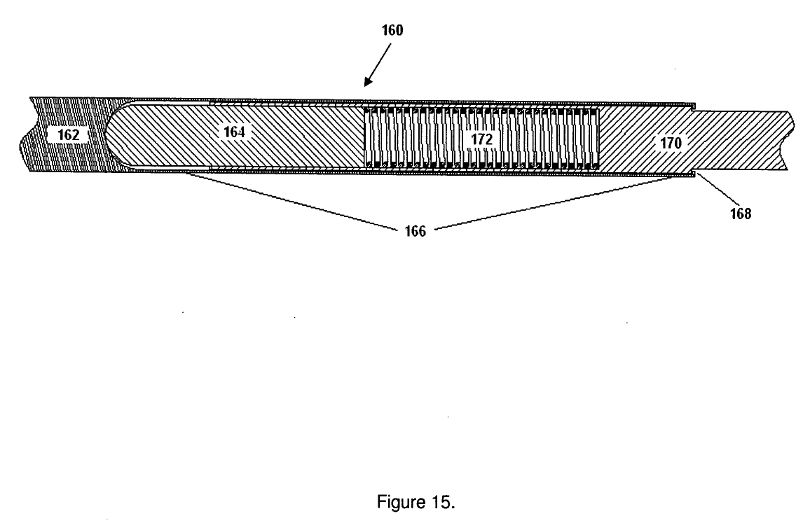

Methods of achieving compressive loading in a single strand ELW are shown in FIGS. 12-17. In FIG. 12, the entire ELW is a spring 130, while in FIG. 13, the ELW comprises a spring portion 132 and a straight wire portion 134. A spring portion may be tapered so that its outer diameter is smallest at its tip. In FIG. 13, spring portion 132 is located at one end of the ELW; however, the spring portion may alternatively be located along any middle section of the ELW. Spring orientation, along its entire length, is preferably maintained by a “lead wire guide assembly” (LWGA), discussed below.

Another method of achieving ELW length flexibility is to use separate, co-linear sections, comprised of at least one spring and at least one straight section, which are compressively loaded such that they provide a continuous electrical path between a sensor or heater element electrode pad or ECS via/pad and the feed-through end of the probe housing. Parallelism of the spring's axis with the probe's longitudinal axis and electrical contact at the spring junctions can be ensured with ELW piston junctions (described next) or LWGAs (discussed below).

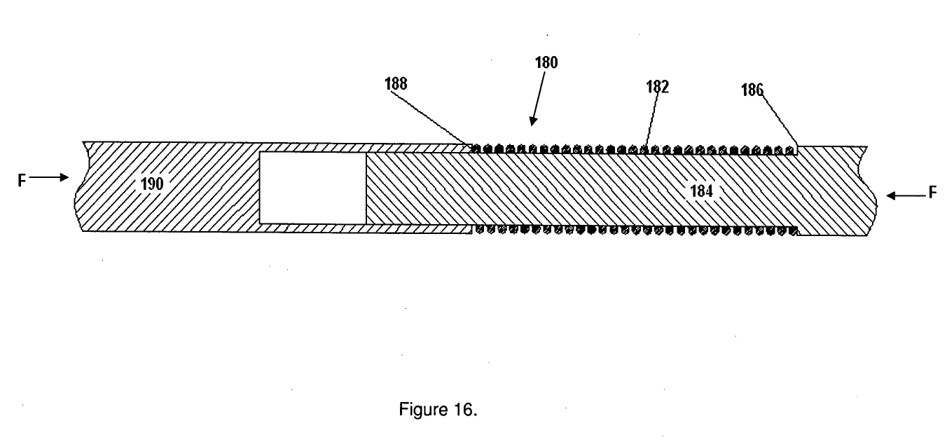

A representative ELW piston junction structure 140 is shown in FIG. 14. The ELW structure comprises a male piston section 142 which slides into a female piston section 144. A spring 146 is located between the top of the male piston and the bottom of the female piston. The spring/male piston junction 148 must be within the female piston at all times. The spring 146 is compressed between the male piston 142 at the spring/male piston junction 148 and the base 150 of the female piston. The minimum spacing between the OD of male piston 142 and the ID of female piston 144 should be at least 0.0005″ at all times. The maximum coil OD of spring 146 should be 0.0005″ less than the ID of female piston 144 at all temperatures. The piston junction 140 may be comprised of three separate parts as shown in FIG. 14, where the ELW's structural integrity is maintained only by compressive forces along the probe's longitudinal axis.

As illustrated in FIG. 15, the piston junction of FIG. 14 might also be constructed as a one-piece spring-loaded ELW piston junction 160. In this example, a section 162 is slid over the piston junction assembly such that it pushes against the end of the male piston 164, with its thin wall 166 crimped at the shoulder 168 of the female piston 170. When so arranged, the maximum extension is limited by the crimp at the female piston shoulder 168. The minimum length is determined, as before, by the compressibility of the coils of spring 172.

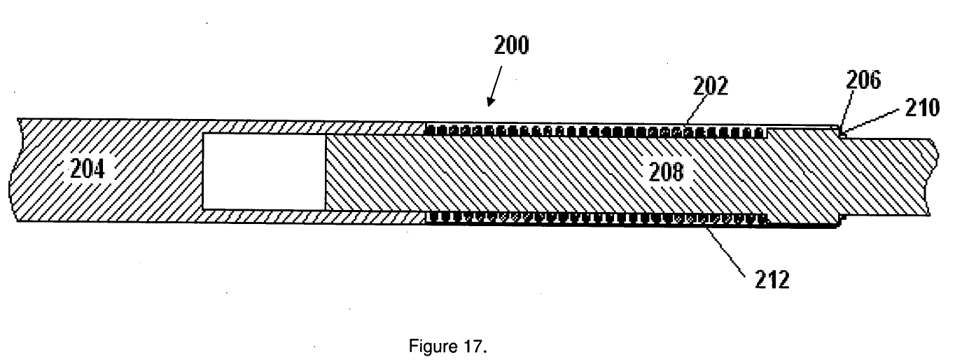

Another representative ELW piston junction structure 180, wherein a spring 182 is guided by the male piston 184, is shown in FIG. 16. Spring 182 is compressed between the base 186 of the male piston and the end 188 of the female piston 190. The spacing between the ID of female piston 190 and the OD of male piston 184 should be at least 0.0005″ at all times. The spacing between the ID of spring coils 182 and the OD of male piston 184 over which the spring is fitted, should be at least 0.0005″ at all times. The piston junction 180 may be comprised of three separate parts as shown in FIG. 16, whose structural integrity is maintained only by compressive forces along the probe's longitudinal axis.

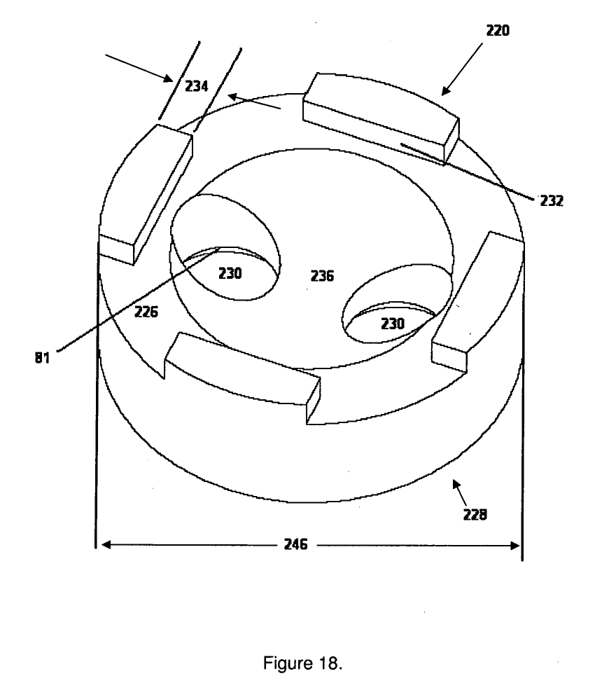

As illustrated in FIG. 17, the piston junction of FIG. 16 might also be constructed as a one-piece spring-loaded ELW piston junction 200. In this example, a thin walled 202 section of the female piston 204 extends beyond the position 206 at which the male piston 2080D decreases. Thin wall section 202 is crimped 210 just beyond the male piston OD transition 206. The maximum extension is limited by the crimp at the male piston OD transition. The minimum length is determined, as before, by the compressibility of the spring coils 212.

To prevent seizing of male/female piston interfaces or spring/piston interfaces, the following material selection criteria is suggested. Normally, it is not desirable to have interfaces that rub against each other comprised of identical metals, with a tungsten-tungsten or tungsten-tungsten carbide interface being exceptions. Metals (other than tungsten) may be identical if at least one of them is coated with a dissimilar metal. Common methods of coating metals include electroplating, diffusion, vacuum deposition and chemical vapor deposition. The metal or metallic alloy used for the straight portion of an ELW and the metal or metallic alloy used for the spring section of an ELW may be different.

In selecting an appropriate spring for an ELW piston junction structure, the modulus of elasticity and yield strength of a metal, as a function of temperature, can be used to determine the minimum number of spring coils, and their spacing, for a particular temperature range.

Criteria for selection of metal or metallic alloys used for the straight wire ELW portions, over the temperature range for which the probe assembly is to be used, include: the metal or metallic alloy does not melt or undergo a phase transformation, is stiff enough to transmit force along the longitudinal axis, and does not chemically react with any of the other components with which it might come into contact.

Criteria for selection of metal or metallic alloys used for the spring portions of an ELW, over the temperature range for which the probe assembly is to be used, in addition to those described above for the straight wire portions, include: the metal or metallic alloy have a high, stable modulus of elasticity and sufficient yield strength at temperature (i.e., it must remain springy). Many metals and metallic alloys can remain springy enough for use at temperatures below 100° C. Above 100° C. and up to 300° C., the preferred metals are stainless steel alloys, platinum:rhodium::60 ^{w}/o:40 ^{w}/o, tungsten or tungsten carbides. Above 300° C. and up to 1000° C., the preferred metals are platinum:rhodium::60 ^{w}/o:40 ^{w}/o, tungsten or tungsten carbides. Above 900° C., tungsten or tungsten carbides are preferred.

The present probe assembly preferably includes an alignment device arranged to ensure alignment between the ELWs and the electrode pads of the sensor or heater element. Such a device is referred to herein as a sensor/lead-wire alignment junction (SLWAJ).

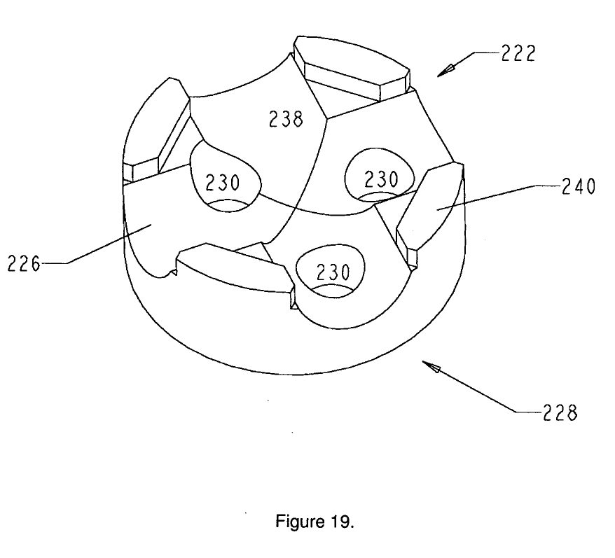

One possible SLWAJ embodiment is shown in FIG. 18. A SLWAJ is preferably made from an electrically insulating ceramic, and serves to align a sensor or heater element with an ECS (if used), and it aligns ELW tips with electrode pads or ECS vias/pads. Examples of two-hole 220, three-hole 222 and four-hole 224 SLWAJs are shown in FIGS. 18-20, respectively. The SLWAJ has first surface 226 and a second surface 228, with the first surface arranged to fit over the top of and make contact with a sensor or heater element. Second surface 228 may be flat or rounded (concave or convex).

The SLWAJ includes ELW guide holes 230 and retainer tabs 232. When in use, the SLWAJ surfaces are perpendicular to the probe's longitudinal axis, with the sensor or heater element held in a particular position with respect to the SLWAJ by retainer tabs 232. When properly arranged, the element's electrode pads are directly below guide holes 230 when the SLWAJ is in place. The probe assembly's ELWs enter the guide holes through second surface 228, and pass through the guide holes to contact the element's electrode pads aligned beneath the guide holes. The diameter and spacing of the guide holes should be such that differences between the expansion coefficients of the sensor or heater element (or ECS) and the SLWAJ do not cause ELW tips to move perpendicular to the probe's longitudinal axis such that electrical contact with the electrode pads or ECS vias/pads is lost.

The thickness 234 of a retainer tab can be non-uniform, but the minimum thickness of at least a portion of a retainer tab should be at least 0.1″, so that the tab will not easily break off during probe assembly and use. A retainer tab wall can have any shape, as illustrated with the SLWAJs shown in FIGS. 18-20.

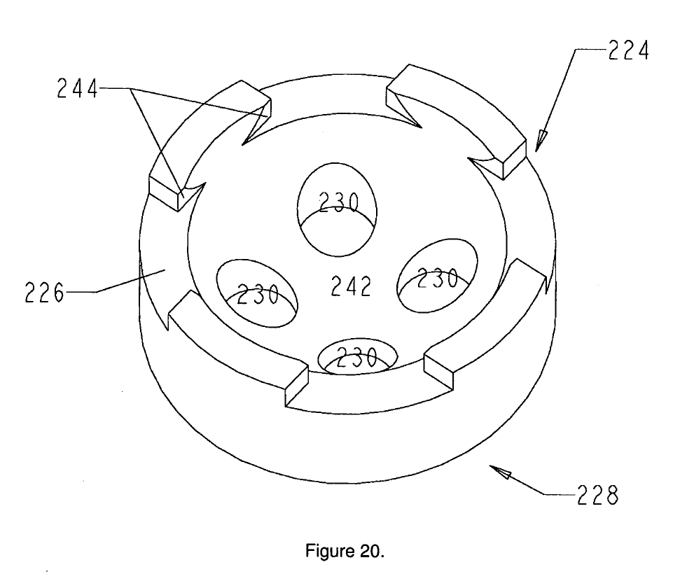

The SLWAJ surface 226 facing the element may be flat or formed by machining or casting to minimize the contact area between the SLWAJ and the element or ECS (if used). Minimizing this contact area minimizes the SLWAJ's effect on sensor response time. The 2-hole SLWAJ 220 of FIG. 18 is shown with a recess pattern 236 ground into its surface. The 3-hole SLWAJ 222 with a deeper recess pattern 238 ground into its surface and with retainer tabs 240 having variable wall lengths is illustrated in FIG. 19. The 4-hole SLWAJ 224 with a rounded recess 242 cast or ground into its first surface and with retainer tabs 244 having variable wall thicknesses is illustrated in FIG. 20.

The distance between opposing SLWAJ retainer tabs, and the dimensions of the sensor or heater element and ECS should be matched such that the length and width dimensions of the element and ECS do not exceed the minimum distance between opposing retainer tabs at all temperatures. This design criterion avoids the possibility of an element or ECS: (a) being broken by compressive forces from the retainer tabs, or, more likely, (b) shearing retainer tabs off of the SLWAJ.

The minimum total length of a SLWAJ (parallel to the probe's longitudinal axis 16) is determined by retainer tab wall length requirements, the ELW insertion depth requirements and SLWAJ/probe wall alignment requirements. If the ELW section making contact to element electrode pads or ECS vias/pads is straight, then the minimum distance between the electrode pads or ECS top surface and the top of the ELW guide hole should be at least 0.005″.

The maximum depth of the retainer tab walls at the SLWAJ rim, and the thickness of the element and ECS (if used) should be such that: (a) the retainer tab walls extend at least 0.005″ beyond the top surface of the element at all temperatures, and (b) the maximum depth of the retainer tab walls is less than the thickness of the element plus the thickness of the ECS (if used) at all temperatures. Thus, the thermal expansion coefficients of the SLWAJ, sensor or heater element and ECS (if used) must be considered together.

The OD 246 of an SLWAJ should be at least 0.0005″ less than the ID of the probe housing over the operating temperature range, thus allowing the SLWAJ to move freely parallel to the probe's longitudinal axis 16 at all temperatures. The total length of the SLWAJ should be at least four times greater than the maximum difference between the SLWAJ OD and the probe housing ID, to ensure that the SLWAJ can always move freely within the housing.

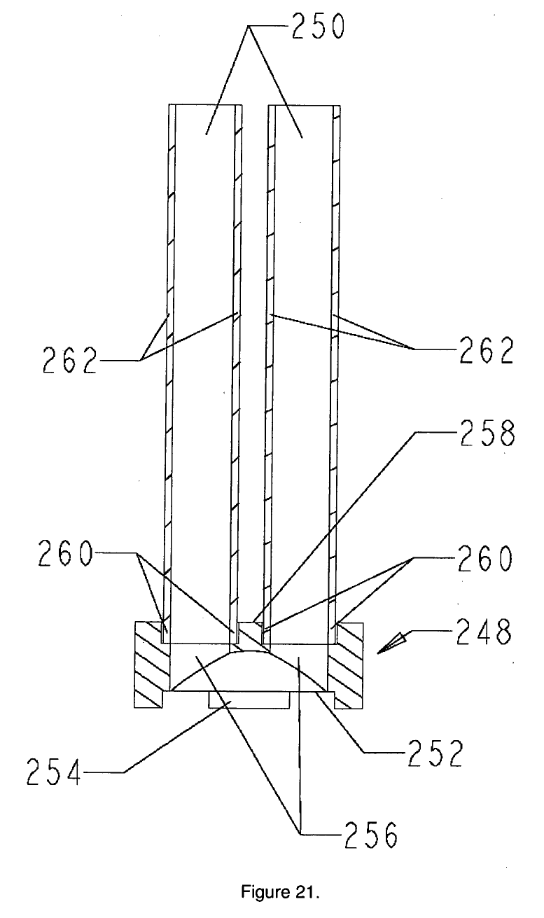

A sectional view of an SLWAJ 248 and incoming ELWs 250 is shown in FIG. 21. The SLWAJ's first surface 252 fits over and presses against the sensor or heater element (not shown), which is held in alignment with the SLWAJ using retainer tabs 254. Two guide holes 256 extend from the SLWAJ's first surface 252 to its second surface 258. The SLWAJ may include a recess 260 or chamfer around the guide hole entrances on second surface 258. As discussed above, the ELWs are preferably routed from the feed-through end to the tip end of the probe assembly by means of a LWGA, which includes conduit tubes 262. Recesses 260 are sized to accommodate tubes 262, so as to prevent the tubes from exerting forces on the ELWs that are perpendicular to the probe's longitudinal axis. A recess or chamfer 260 is necessary if the ELW tip making contact with the element's electrode pad is a spring. In this way, a compressive force applied to the top of the LWGA is be conveyed to the SLWAJ, and then in turn to the sensor or heater element, such that the element is held in place against the probe tip.

As noted above, a lead-wire guide assembly (LWGA) provides a pathway for electrical lead-wires (ELWs). An LWGA may also act to maintain ELW alignment within the probe housing, and to ensure that ELWs remain electrically isolated from each other. The ELW paths are parallel to the probe's longitudinal axis 16, and extend from the feed-through end of the probe housing to the sensor or heater element. The LWGA components move parallel to the probe's longitudinal axis 16, and independently of the probe walls and the ELWs. The LWGA exerts pressure on the top surface of the SLWAJ (if used) at all times. The ID of the ELW paths are such that straight and spring portions of the ELWs remain parallel to the probe's longitudinal axis and do not buckle. The difference between the ID of an ELW guide path and an ELW OD or spring coil OD should be at least 0.0005″ at all temperatures.

The basic components of a LWGA are: (1) at least one springs, one or more large OD conduit tubes, and one or more small OD conduit tubes. These components are stacked along the probe's longitudinal axis, between the SLWAJ (if used) and feed-through end. The LWGA should contain at least one large OD conduit tube, which may or may not contain the SLWAJ at one end.

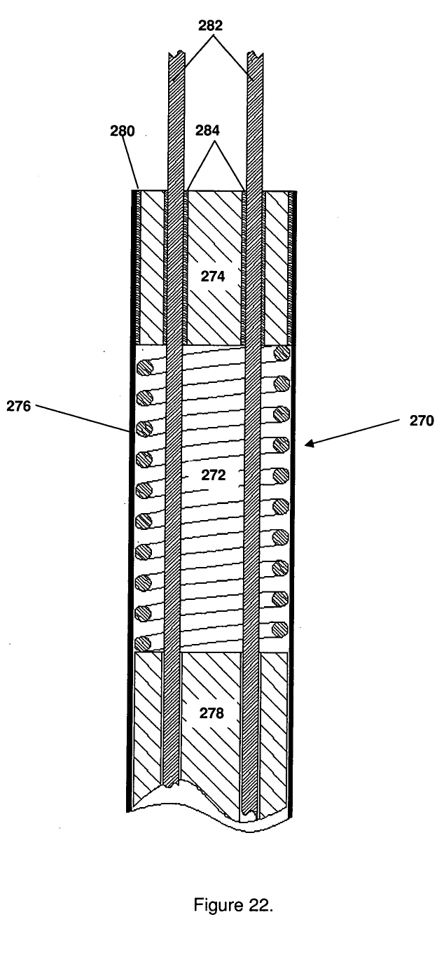

One possible embodiment of an LWGA 270 is shown in FIG. 22. Here, a spring 272 is compressed between an electrical feed-through 274 affixed to the probe housing 276 at its feed-through end, and a large OD conduit tube 278 that is free to move parallel to the probe's longitudinal axis. In this configuration, spring 272 compresses the conduit 278 towards the SLWAJ (not shown) at the tip end of the probe housing. Feed-through 274 is bonded to the probe housing 276 with, for example, a bonding material 280. The ELWs 282 are bonded to feed-through 274 with, for example, a bonding material 284, but they are free to move within the large OD conduit tube 278.

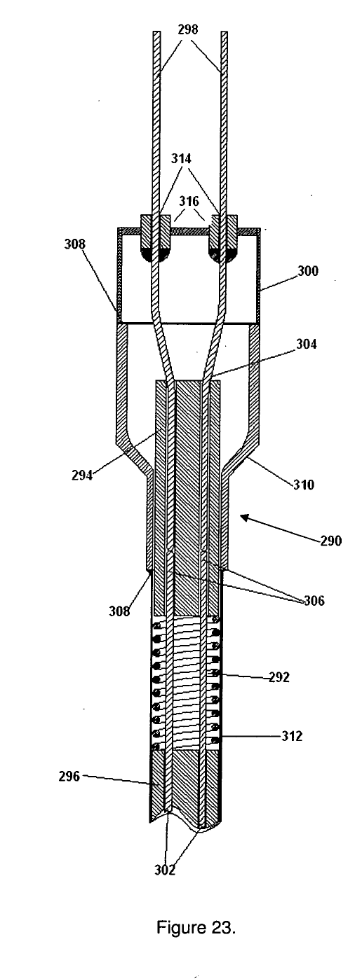

Another possible LWGA configuration 290 is shown in FIG. 23. Here, a spring 292 is compressed between two large OD conduit tubes 294, 296. In this example, there are two sets of ELWs: a first set 298 affixed to an electrical feed-through 300, and a second set 302 at the tip end of the housing. The conduit tube 294 nearest the electrical feed-through 298 is trapped at the bends of the feed-through ELWs 298, at their entry point 304 into conduit tube 294. The second conduit tube 296 is free to move parallel to the probe's longitudinal axis 16. In this configuration, large OD conduit tube 294 performs the function of establishing ELW alignment with the sensor or heater element electrode pads. The feed-through ELWs 298 make contact with the straight ELW tips 302 at a contact point 306; the spring portions of ELWs 302 are located below the point at which the probe housing is cut off in FIG. 23, and therefore is not shown. Spring 292 compresses the conduit tubes below it together and towards the SLWAJ. The electrical feed-through 300 is preferably welded 308 to a reduction tube 310, which is preferably welded to the probe wall 312. Feed-through ELWs 298 are preferably brazed 314 to electrically insulating ceramic inserts 316 which are brazed to electrical feed-through 300. The feed-through ELWs 298 are free to expand and contract within the trapped large OD conduit tube 294. The ELWs tips 302 are free to move within both large OD conduits 294 and 296. The difference between the ID of the probe 312 and the OD of spring 292 should be at least 0.0005″ at all temperatures.

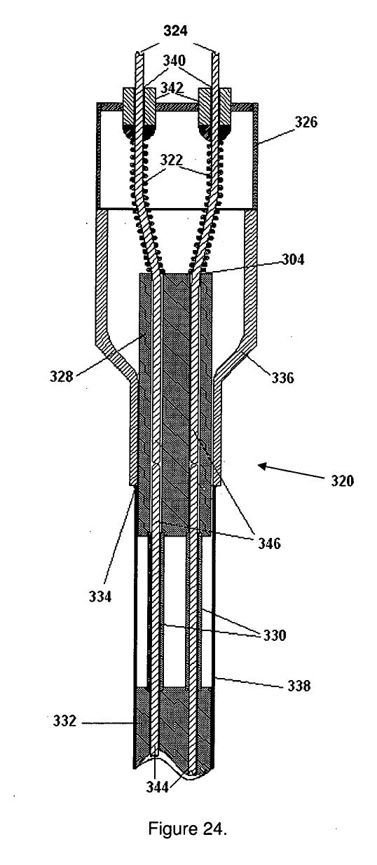

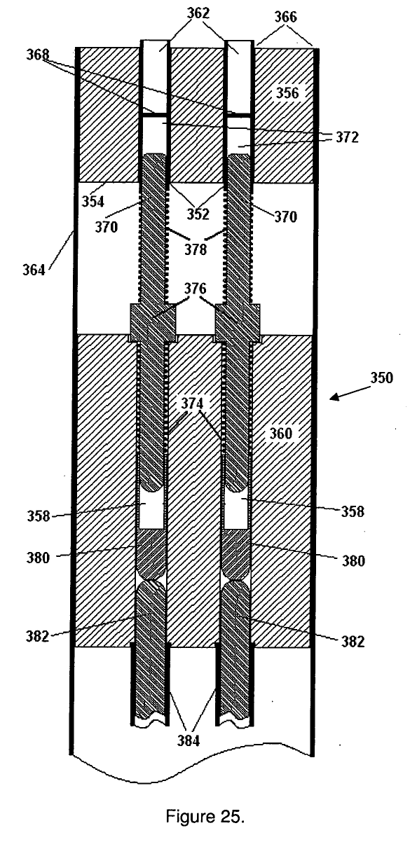

Another possible LWGA embodiment 320 is shown in FIG. 24. Here, springs 322 are placed coaxially, over each of the feed-through ELWs 324, between an electrical feed-through 326 on one end, and a large OD conduit tube 328 that is free to move parallel to the probe's longitudinal axis 16 at the other end. The LWGA also includes small OD conduit tubes 330 below tube 328, and large OD conduit tube 332 below tubes 330. The springs 322 compress the conduits 328, 330, 332 together and towards the SLWAJ. The electrical feed-through 326 is preferably welded 334 to a reduction tube 336, which is preferably welded 334 to the probe wall 338. Feed-through ELWs 324 are preferably brazed 340 to electrically insulating ceramic inserts 342, which are preferably brazed to electrical feed-through 326. The large OD conduit tubes 328, 332 are free to move parallel to the probe's assembly's longitudinal axis 16. The feed-through ELWs 324 and probe tip ELWs 344 are free to move within the guide paths (holes) of large OD conduit tubes 328, 332. The feed-through ELWs 324 make contact with the straight ELW tips 344 at position 346; the spring section of the ELWs is located below the probe housing cutoff.

The spring metal or metallic alloy must have a high, stable modulus of elasticity and sufficient yield strength to ensure that it remains springy at all temperatures. The number of coils and their spacing must be sufficient to ensure that: (1) spring loaded pressure is maintained against the top of the SLWAJ at maximum probe operating temperature, and (2) the spring(s) do not collapse to minimum length (coils touching each other) at minimum probe operating temperature. The difference between the OD of the feed-through ELW 324 and the ID of spring 322 should be at least 0.0005″ at all temperatures.

As shown in FIG. 25, an LWGA 350 might be constructed using piston junctions instead of springs to compress the large and small OD conduit tubes together and towards the SLWAJ. The spring loading of the LWGA is accomplished by piston junctions 352 located across the surface 354 of an electrical feed-through 356—see FIGS. 15 and 16 for piston junction details. The spring loading of the ELWs is accomplished by piston junctions 358 located inside the ELW guide paths of the large OD conduit 360. EFT 356 is preferably a ceramic disk containing two hollow metallic pins 362. The ceramic disk is preferably attached to the pins and to the probe wall 364 by a bonding material 366. The hollow volume of pins 362 is separated by a metallic diaphragm 368. The male pins 370 of piston junctions 352 are free to move up and down within the lower volume 372 of pins 362, where the pins perform the same function as part 190 in FIG. 16. Force is applied by piston junctions 352, through springs 374 to the large OD conduit 360 by larger diameter sections 376 of the pins 370. The coils 378 and female sections 380 of piston junctions 358 are free to move within the ELW guide paths of large OD conduit 360. Straight ELW portions 382 make contact with the ends of female sections 380 inside large OD conduit 360. The straight ELW portions 382 extend downward, through small OD conduits 384, towards the sensor or heater element electrode pads or ECS vias.

A large OD conduit maintains ELW alignment with the probe's longitudinal axis and provides electrically insulating paths for heater coil lead-wires. The difference between the OD of a large OD conduit and the ID of the probe wall should be at least 0.0005″. The diameter of the electrical paths and the spacing of electrical paths within the large OD conduit must be dimensioned such that a straight path between the SLWAJ and the electrical terminal junction (discussed below) is maintained at all temperatures for each ELW; this ensures that ELW sections which cross SLWAJ/LWGA-conduit tube interfaces are not prevented from moving freely parallel to the probe's longitudinal axis due to misalignment caused by differences in thermal expansion coefficients.

The length of a large OD conduit tube, parallel to the probe's longitudinal axis, should be at least four times the difference between the OD of the tube and the ID of the probe housing at all temperatures. A large OD conduit tube should remain electrically insulating at all temperatures. The spacing between ELW paths in a large OD conduit tube should be such that ELW piston junctions, exposed side-by-side, do not touch each other at any temperature. A large OD conduit tube is preferably arranged such that it mates most effectively with small OD conduit tubes if it is recessed (counter-bored or chamfered) at the mating interface with the small OD conduit tube, to prevent small OD conduit tubes from exerting forces on ELWs that are perpendicular to the probe's longitudinal axis 16.

A small OD conduit tube can contain one ELW guide path or multiple ELW guide paths.

Small OD conduit tubes containing a single guide path are preferably aligned side-by-side, parallel with the probe's longitudinal axis, with one guide path for each ELW. Small OD single path conduit tubes may be used to enclose ELWs between: (1) an SLWAJ and a large OD conduit tube, (2) two large OD conduit tubes, and (3) between a large OD conduit and an electrical terminal junction (discussed below). The wall thickness of a small OD conduit tube should be as small as possible to minimize heat transfer along probe axis 16. Small OD single path conduit tubes may be ceramic or metal, but can only be metallic if they do not touch.

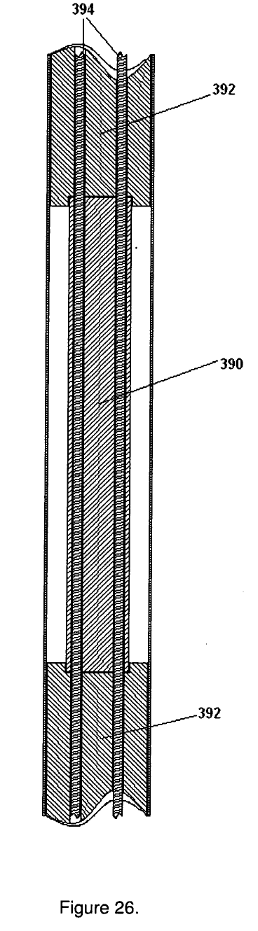

As noted above, small OD conduit tubes might also contain multiple guide paths. These types of conduit tubes can be used to guide and enclose ELWs between: (1) the SLWAJ and a large OD conduit tube, (2) two large OD conduit tubes, or (3) a large OD conduit tube and an electrical terminal junction (discussed below). One possible example of a multiple guide path, small OD conduit tube 390 between two large OD conduit tubes 392 and enclosing ELWs 394, is shown in FIG. 26.

The spacing between ELW paths of a small OD conduit tube should be such that exposed side-by-side ELW piston junctions do not touch at any temperature. The diameter of the electrical paths and the spacing of electrical paths within small OD, multiple guide path conduit tubes should be dimensioned such that a straight path between the SLWAJ and the electrical terminal junction (discussed below) is maintained at all temperatures, for each ELW, and such that ELW sections that cross SLWAJ/large OD conduit tube interfaces are not prevented from moving freely parallel to probe axis 16 because of misalignment due to differences in thermal expansion coefficients.

An electrical feed-through (EFT) is affixed to the feed-through end of a probe housing. Methods of attaching EFTs to probe housings include: adhesive bonding, viscous seal bonding, welding, brazing, soldering, threaded connectors (e.g., NPT) and vacuum component attachments [e.g., compressed O-ring seal fittings and metal to metal seal fittings (e.g., conflat, VCR, A-lock)].

There are two basic EFT types: (1) an electrically insulating polymer or ceramic disk containing a plurality of metal electrodes, and (2) a metallic disk, containing a plurality of electrically insulating polymer or ceramic tubes, wherein each tube contains a metal electrode. The electrodes are the electrically conductive paths through both EFT types. The spacing between electrodes must be such that the electrodes and ELWs do not short to each other by touching or arcing at any probe temperature.

In the electrically insulating polymer or ceramic disk type EFT, the electrodes may be embedded within the disk by compression and/or bonding, brazing or viscous flow. In a metallic disk type EFT, the electrically insulating polymer or ceramic tubes—containing brazed or bonded metal electrodes—are arrayed within holes in the metallic disk and attached by compression and/or bonding, brazing or viscous flow.

If the ELW tips terminate at the EFT electrodes (as in FIG. 22), then the EFT electrode size and electrode spacing should be such that the ELWs are not trapped, bent or crimped by misalignment with the ELW guide paths of the nearest LWGA conduit tube, due to differences in the expansion coefficients of the EFT and the LWGA conduit tubes. These constraints do not apply if, e.g., the ELWs are terminated as shown in FIGS. 23-24.

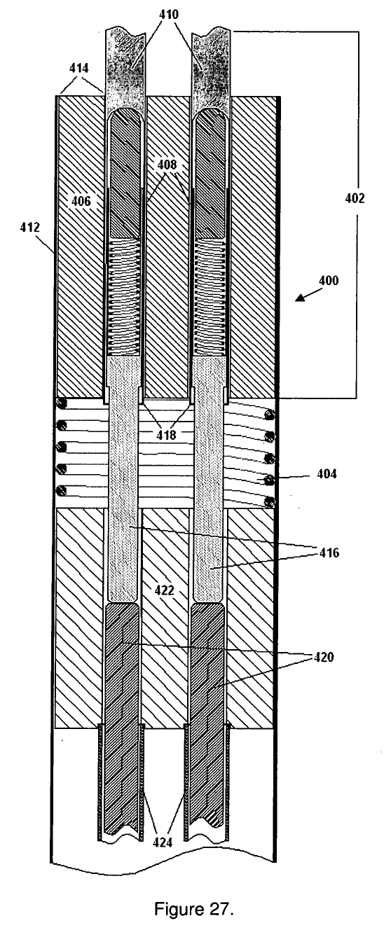

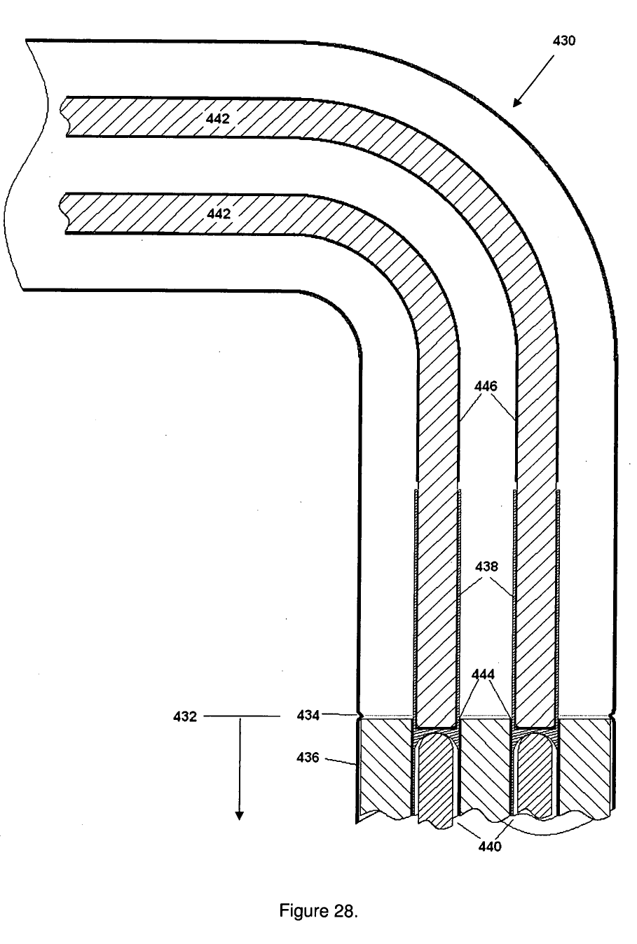

An example of an EFT 400 containing female piston junctions is shown in FIG. 27. In this illustration, the piston junctions 402 compensate for ELW expansion and contraction, while pressing the ELW tips towards the sensor or heater element electrode pads. A spring 404 compensates for LWGA conduit tube and SLWAJ expansion and contraction, while pressing the LWGA conduit tubes and SLWAJ towards the probe tip. In this illustration, the EFT is a ceramic disk 406 containing two piston junctions. The ceramic disk is attached to the thin walled section 408 of stationary section 410 of the piston junctions and to the probe wall 412 by a bonding material 414. The end of the thin walled section 408 of stationary section 410 is crimped so that it limits the maximum extension of the shoulder of the female piston 416 at position 418. ELWs may be attached to the portion of stationary section 410 extending out the top of the EFT. The ELW tips 420 contact the female pistons 416 inside the guide paths of a large OD conduit tube 422. The ELW tips 420 are shown extending into small OD conduit tubes 424.

Instead of an electrical feed-through, which is affixed to the probe housing, the present probe assembly can employ an electrical terminal junction (ETJ) at the feed-through end. An ETJ is a component which contains a plurality of electrically conductive paths, parallel to the probe's longitudinal axis 16, but is not affixed to the probe housing.

Methods of entrapping an ETJ include crimping, or affixing a hollow cylindrical part to the terminal end of the probe housing, where the ID of the cylindrical part is smaller than the OD of the ETJ, or bending the probe.

There are two basic ETJ types: (1) an electrically insulating polymer or ceramic disk containing a plurality of metal electrodes, and (2) a metallic disk, containing a plurality of electrically insulating polymer or ceramic tubes, wherein each tube contains a metal electrode. The electrodes are the electrically conductive paths through both ETJ types. The spacing between electrodes must be such that the electrodes and ELWs do not short to each other by touching or arcing, at any probe temperature. In the electrically insulating polymer or ceramic disk type ETJ, the electrodes may be embedded within the disk by compression and/or bonding, brazing or viscous flow. In a metallic disk type ETJ, the electrically insulating polymer or ceramic tubes—containing brazed or bonded metal electrodes—are arrayed within holes in the metallic disk and attached by compression and or bonding, brazing or viscous flow.

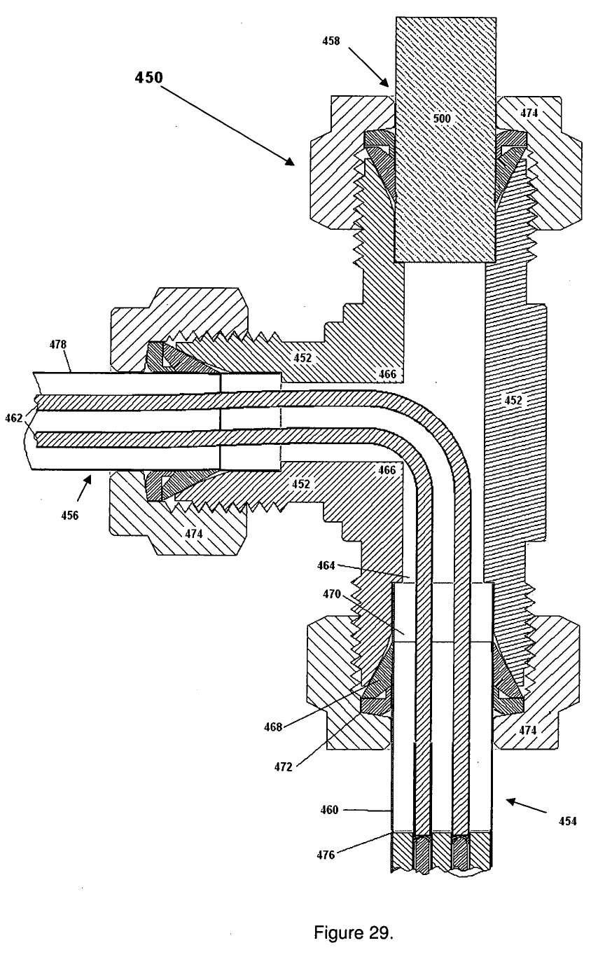

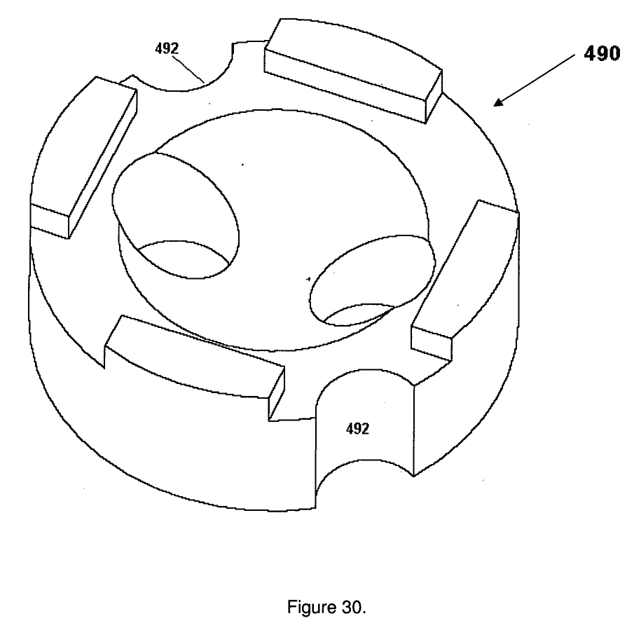

The housing might be an ‘angled probe housing’ (APH), rather than a straight housing. This can be desirable for reasons including positioning the EFT out of the line of site of a thermal radiation path, and constraints imposed by equipment dimensions. Independent spring loading of ELWs and LWGAs in a metal APH is illustrated in FIGS. 28-29 using a single 90° angle. The same basic concepts apply to metal or ceramic APHs of any configuration. Metallic tubes and fittings are used to illustrate APHs; however, APHs can be made with all-ceramic tubes or a combination of metallic and ceramic tubes. A Swagelok union tee, used in this section to illustrate an APH, is just one of numerous fittings that can be employed to create an APH.

Two types of 90° APHs are illustrated in FIGS. 28 and 29. A single component APH, created by bending a metal tube, is shown in FIG. 28. An APH created by joining two metal tubes with a Swagelok union tee is shown in FIG. 29-a union tee is used instead of a union elbow in this example to facilitate the discussion below of atmosphere control within probe housings.

In a single component APH 430, created by bending a metal tube (FIG. 28), the normal probe housing 432 terminates at the crimp 434; a portion of the ETJ is shown below the crimp. The ETJ is identical to the EFT in FIG. 27 except that: (1) the ETJ is not bonded to probe wall 436, and (2) the stationary section 438 of the piston junctions 440 is extended upward, beyond the crimp 434 as a hollow tube. ELWs 442 are affixed to the inside of the hollow tubes by brazing, bonding or soldering material 444; note that ELWs 442 may also be welded to the inside of the hollow tubes. ELWs 442 are shown covered by an electrically insulating material 446; one suitable insulating material is Nextel (1200° C. rating for continuous use). If higher temperatures are required, ELWs 442 can be electrically insulated—and still remain flexible—by covering them with a string of short ceramic tubes. The APH 430 is created by bending the tube above the hollow tube portion of the stationary section 438, after crimp 434 is made in probe housing wall 436. ELWs 442 extend to an EFT (not shown) at the end of the 90° bend section.

An APH 450 created by joining two metal tubes with a Swagelok union tee 452 is shown completely assembled in FIG. 28. The bottom port 454 and the side port 456 are discussed here; the top port 458 is discussed below.

The tube wall 460 and ELWs 462 of the probe assembly are inserted into the tee 452, lead wires first. Tube wall 460 is inserted into tee 452 to its maximum allowable depth 464. If more cross-section is required to thread ELWs 462 into side port 456, then the corners 466 of tee 452 can be machined off to widen the cross-section of the opening within the tee by drilling through the wall of the tee opposite the side port, and then welding a plug into the wall of the tee.

The tube wall 460 is preferably compression sealed by a front ferrule 468, which is compressed into the tube wall at position 470. The front ferrule 468 is compressed into the tube wall by pressure from the back ferrule 472. Pressure is exerted on the back ferrule by tightening nut 474.

The normal probe housing terminates at the crimp 476. The assembly within the probe housing below the crimp is identical to that shown in FIG. 28. A tube 478 is slid over ELWs 462 and into side port 456, where it is connected to tee 452 in the same manner as described above for tube wall 460. The ELWs 462 are connected to an electrical feed-through at the opposite end of tube 478 by any method desired.

The durability of the electrical interfaces extending from sensor or heater elements to EFTs along ELW paths, and the durability of sensors, ELWs and LWGA spring materials, can be adversely affected by the atmosphere within a probe housing. At temperatures at or below 0° C., the most important concern is water vapor, which can condense inside a probe housing, leading to probe failure at electrode interfaces. At temperatures above 0° C., the most important concern is oxidation of sensors and metallic components. Methods and structures that facilitate probe bake out, atmospheric displacement within a probe housing or evacuation of a probe housing are described below.

Additional holes may be included within or along the edges of the SLWAJ, the large OD conduit tubes of the LWGA, and the ETJ to provide diffusion paths for evacuation or exchange of gas within the PROBE housing. A two-wire SLWAJ 490 containing two diffusion paths 492 is shown in FIG. 30. To function most effectively, the diffusion paths of all the large OD components of an LWGA should be aligned with each other and with the diffusion paths 492 of the SLWAJ. Diffusion paths 492 should be located symmetrically about the center of the probe. More diffusion paths are better for two reasons: (1) gas volumes are more easily replaced or evacuated, and (2) the response time of the sensor or heater element is improved because it is in contact with less thermal mass.

EFTs must contain metals and electrical insulators (usually ceramics). Because of differences in expansion coefficients, the highest temperature at which an EFT will maintain a vacuum tight seal is about 450° C. Practical methods that can be used to ensure that the probe housing remains vacuum sealed at high temperatures include: (1) cooling the probe's feed-through end containing an EFT, (2) adding a glass seal overlayer to the top of the EFT, (3) making a very long probe, or (4) creating an APH with the EFT located away from the thermal radiation path along the probe wall.

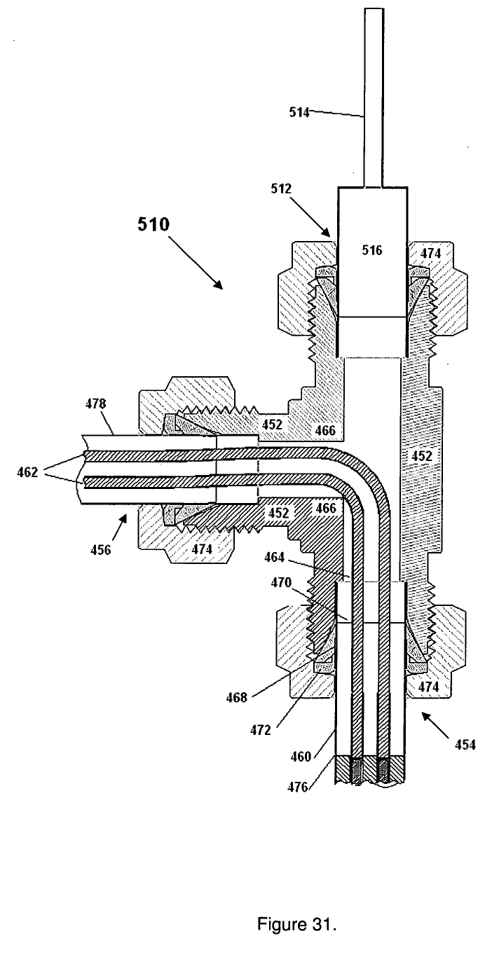

In the APH 430 in FIG. 28, the desired atmosphere within the APH must be established and maintained until the EFT is connected and sealed. In the APH 450 in FIGS. 29 and 31, the APH can be completed before the atmosphere within the APH is established.

The APH 450 in FIG. 29 is shown with a metal plug 500 in the top port 458. This sealing method requires that the top port be contained within an environmental control chamber, e.g., a glove box, where, the top port opening can be sealed from the external atmosphere at the probe wall surface or at the tube extension emanating from the side port 456.

The APH 510 in FIG. 31 is similar to that of FIG. 29, except that a dual diameter tube exits from the top port 512. The large diameter tube section 514 is welded to a small diameter tube section 516. The wall of large diameter tube 514 can be inserted through a vacuum seal O-ring so that only the dual diameter tube need be inside an environmental chamber. The opening of the small diameter tube section 516 can be sealed or crimped and sealed by welding, brazing, soldering, etc; alternatively, a vacuum seal cap can be connected to the end of the small diameter tube section. After sealing small diameter tube section 516, the APH 510 can be removed from the environmental chamber by sliding the dual diameter tube and cap (if used) through the O-ring seal.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

We claim:

1. A probe assembly for housing and providing electrical contact to planar or chip-type sensors and heaters, comprising:
a probe housing having a tip end and a feed-through end and an associated longitudinal axis;
a sensor or heater element within said housing, said element having top and bottom surfaces, said top surface including electrode pads for said element, said assembly arranged such that said bottom surface is in thermal contact with said probe tip and said top and bottom surfaces are perpendicular to said longitudinal axis;
a means of applying a first compressive force to said sensor or heater element such that thermal contact between said bottom surface and said probe tip is maintained; and
electrical lead wires (ELWs) within said housing which provide respective conductive paths between each of said electrode pads and said feed-through end, each of said ELWs including a means of providing a second compressive force that acts to maintain physical and electrical contact between said ELW and its respective electrode pad;
said assembly arranged such that said first compressive force is independent of said second compressive force.

2. The probe assembly of claim 1, wherein said first and second compressive forces are applied parallel to said longitudinal axis.

3. The probe assembly of claim 1, wherein said housing comprises one or more sections, each of which has a respective diameter or width and cross-sectional shape perpendicular to said longitudinal axis, wherein each of said cross-sectional shape are round, oval, rectangular or square.

4. The probe assembly of claim 1, wherein said means of providing said second compressive force comprises a spring.

5. The probe assembly of claim 1, wherein the shape of said probe tip with respect to said longitudinal axis is flat, rounded, or conical.

6. The probe assembly of claim 3, wherein said probe tip is arranged to accommodate the attachment of a member which extends beyond probe tip when attached such that thermal contact between said element and the end of said member opposite said probe tip is maintained.

7. The probe assembly of claim 6, wherein said probe tip and member are arranged such that said member can be threaded onto said probe tip.

8. The probe assembly of claim 7, wherein said member is a solder tip.

9. The probe assembly of claim 1, wherein said probe tip includes a recessed area arranged to receive and accommodate a member or a fluid sample to be heated or vaporized within said recessed area.

10. The probe assembly of claim 1, wherein said housing comprises a metal, metal alloy or a ceramic.

11. The probe assembly of claim 1, further comprising a thermal contact insert (TCI) located between said element and said probe tip arranged to align said element such that its electrode pads are approximately perpendicular to said longitudinal axis and to provide a thermal contact path between said tip and said element.

12. The probe assembly of claim 1, wherein said sensor or heater element is a planar thin-film sensor.

13. The probe assembly of claim 1, further comprising an electrical contact standoff (ECS) inserted between the ends of the ELWs nearest said element and said element, said standoff arranged to distribute said second compressive force over a larger area.

14. The probe assembly of claim 1, wherein each of said ELWs comprises separate co-linear sections comprised of said at least one spring section and one straight wire section, said co-linear sections compressively loaded to provide a continuous electrical path between said electrode pads and said feed-through end.

15. The probe assembly of claim 14, wherein said co-linear sections are compressively loaded by means of a piston junction.

16. The probe assembly of claim 15, wherein said separate co-linear sections comprise:
a female piston section;
a male piston section which slides linearly into said female piston section; and
a spring positioned within said female piston section at the top of said male piston section such that said spring is compressed between the top of said male piston section and the base of said female piston section.

17. The probe assembly of claim 16, wherein said female piston section includes a shoulder, further comprising a co-linear section arranged to slide over said male piston section and said female piston section such that the base of said female section is in contact with the end of said male piston section and the end of said female section opposite said base is crimped at said shoulder, such that the maximum extension of said female section is limited by said crimp.

18. The probe assembly of claim 15, wherein said separate co-linear sections comprise:
a female piston section;
a male piston section which slides linearly into said female piston section, said male piston section having a shoulder; and
a spring positioned over said male piston section between said shoulder and said female piston section such that said spring is compressed between the top of said female piston section and the shoulder of said male piston section.

19. The probe assembly of claim 18, wherein said male piston section has a second shoulder and the top of said female piston section extends over said spring and is crimped at said second shoulder, such that the maximum extension of said female section is limited by said crimp.

20. The probe assembly of claim 1, further comprising an alignment device arranged to ensure alignment between said ELWs and said electrode pads, said alignment device comprising:
a first surface;
a second surface opposite said first surface;
a raised retaining means on said first surface, said first surface and said retaining means arranged to be placed over the top surface of said sensor or heater element and to maintain said element in a desired position with respect to said alignment device when so placed, said first and second surfaces being perpendicular to said probe axis when in place over said element; and
guide holes which pass from said first surface to said second surface, each of said guide holes aligned with a respective one of said electrode pads when said alignment device is placed over the top surface of said element,
said assembly arranged such that, when in place over said element, said alignment device and thereby said sensor or heater element is subject to said first compressive force.

21. The probe assembly of claim 20, wherein a portion of the first surface of said alignment device is recessed so as to minimize the contact area between said alignment device and said sensor or heater element.

22. The probe assembly of claim 20, wherein at least a portion of said ELWs are enclosed within respective conduit tubes, said guide holes chamfered, counter-bored or surrounded by respective recessed areas sized to accommodate said conduit tubes.

23. The probe assembly of claim 20, further comprising an electrical lead wire guide assembly (LWGA) comprising:
one or more conduit tubes through which at least a portion of said ELWs pass, at least one of said tubes being in contact with the second surface of said alignment device; and
one or more springs which exert said first compressive force on said conduit tubes, said conduit tubes and springs stacked within said probe housing along said longitudinal axis;
such that said LWGA moves independently of said probe housing and said ELWs.

24. The probe assembly of claim 23, further comprising an electrical feed-through at the feed-through end of said probe housing and affixed to the inner walls of said housing, said LWGA springs located between said feed-through and at least one of said conduit tubes.

25. The probe assembly of claim 24, wherein a portion of each of said ELWs passes through and is affixed to said electrical feed-through,
such that said LWGA, said conduit tubes and said alignment device move independently of said ELWs and said probe housing.

26. The probe assembly of claim 23, wherein said one or more conduit tubes comprise at least one conduit tube having at least two through-holes through which respective ELWs can be routed, said at least one conduit tube arranged such that said through-holes are physically separate and electrically isolated from each other.

27. The probe assembly of claim 23, wherein said one or more springs comprise piston junctions.

28. The probe assembly of claim 1, further comprising an electrical feed-through affixed to the feed-through end of said housing, said feed-through containing a plurality of metal electrodes oriented parallel to said longitudinal axis and arranged to convey signals external to said probe assembly to and from said ELWs.

29. The probe assembly of claim 28, wherein said feed-through comprises:
an electrically insulating polymer or ceramic disk, said plurality of metal electrodes embedded within said disk.

30. The probe assembly of claim 28, wherein said feed-through comprises:
a metallic disk; and
a plurality of insulating polymer or ceramic tubes embedded within said disk, said plurality of metal electrodes contained within respective tubes.

31. The probe assembly of claim 28, wherein said feed-through electrodes include piston junctions arranged to compressively load said ELWs such that they are pressed towards said sensor or heater element.

32. The probe assembly of claim 1, further comprising an electrical terminal junction (ETJ) which is not directly affixed to said housing, said ETJ containing a plurality of metal electrodes oriented parallel to said longitudinal axis and arranged to convey signals external to said probe assembly to and from said ELWs.

33. The probe assembly of claim 32, wherein said ETJ comprises:
an electrically insulating polymer or ceramic disk, said plurality of metal electrodes embedded within said disk.

34. The probe assembly of claim 32, wherein said ETJ comprises:
a metallic disk; and
a plurality of insulating polymer or ceramic tubes embedded within said disk, said plurality of metal electrodes contained within respective tubes.

35. The probe assembly of claim 1, wherein said probe housing is angled such that said feed-through end is not linearly aligned with said tip end.

36. The probe assembly of claim 1, wherein said probe assembly includes diffusion paths arranged to effect the evacuation or exchange of gasses from within said probe housing.

37. A probe assembly for housing and providing electrical contact to planar or chip-type sensors and heaters, comprising:
a probe housing having a tip end and a feed-through end and an associated longitudinal axis;
a sensor or heater element within said housing, said element having top and bottom surfaces, said top surface including electrode pads for said element, said assembly arranged such that said bottom surface is in thermal contact with said probe tip and said top and bottom surfaces are perpendicular to said longitudinal axis;
a means of applying a first compressive force to said sensor or heater element such that thermal contact between said bottom surface and said probe tip is maintained; and
electrical lead wires (ELWs) within said housing which provide respective conductive paths between each of said electrode pads and said feed-through end, each of said ELWs including at least one spring portion which provides a second compressive force that acts to maintain physical and electrical contact between said ELW and its respective electrode pad, said first and second compressive forces are applied parallel to said longitudinal axis;
an alignment device arranged to ensure alignment between said ELWs and said electrode pads, said alignment device comprising:
a first surface;
a second surface opposite said first surface;
a raised retaining means on said first surface, said first surface and said retaining means arranged to be placed over the top surface of said sensor or heater element and to maintain said element in a desired position with respect to said alignment device when so placed, said first and second surfaces being perpendicular to said probe axis when in place over said element; and
guide holes which pass from said first surface to said second surface, each of said guide holes aligned with a respective one of said electrode pads when said alignment device is placed over the top surface of said element,
said assembly arranged such that, when in place over said element, said alignment device and thereby said sensor or heater element is subject to said first compressive force; and
an electrical lead wire guide assembly (LWGA) comprising:
one or more conduit tubes through which at least a portion of said ELWs pass, at least one of said tubes being in contact with the second surface of said alignment device; and
one or more springs which exert said first compressive force on said conduit tubes, said conduit tubes and springs stacked within said probe housing along said longitudinal axis;
such that said LWGA moves independently of said probe housing and said ELWs;
said assembly arranged such that said first compressive force is independent of said second compressive force.

38. A method of ensuring electrical contact between electrical lead wires (ELWs) and respective electrode pads on a sensor or heater element located at the tip end of a probe housing and of maintaining thermal contact between said sensor or heater element and the tip end of a probe housing, comprising:
applying a first compressive force to said sensor or heater element such that thermal contact between said bottom surface and said probe tip is maintained; and
applying a second compressive force independent of said first compressive force that acts to maintain physical and electrical contact between said ELWs and their respective electrode pads.

39. The method of claim 38, further comprising:
providing one or more conduit tubes through which at least a portion of said ELWs pass; and
providing one or more springs which exert said first compressive force on said conduit tubes, said conduit tubes and springs stacked within said probe housing such that said first compressive force causes thermal contact between said bottom surface and said probe tip to be maintained.
